(19) United States
(12) Patent Application Publication
(10) Pub. No.: US 2004/0144976 A1
(43) Pub. Date: Jul. 29, 2004

(54) Light emitting diode, support & method of manufacture

(76) Inventors: Brahim Dahmani, Bourron Marlotte (FR); Guillaume Guzman, Veneux-les-Sablons (FR)

Correspondence Address: CORNING INCORPORATED, SP-TI-3-1, CORNING, NY, 14831

(21) Appl. No.: 10/654,461

(22) Filed: Mar. 3, 2004

(30) Foreign Application Priority Data
Sep. 3, 2002 (FR) 02 10868

(51) Int. Cl. H01L 35/24; H01L 51/00

(52) U.S. Cl. 257/40

(57) ABSTRACT

A light emitting diode of the stacked-layer structure type, incorporating at least one layer made of an inorganic material between the layer forming the substrate and a layer forming the light emitting layer, is provided, in which a periodic structure at the wavelength range emitted by the light emitting layer is printed.

Also described is a method for generating a microstructure periodic with a wavelength range of the emitting layer of a light emitting diode. The method includes: depositing an inorganic material layer by a sol-gel process between the substrate and a light emitting layer, and printing the periodic structure onto the outer surface of this layer by soft lithography, as well as using this process for manufacturing a light emitting diode.

### RELATED APPLICATION

This application claims the benefit of priority from French Patent Application No. 02-10868, filed, Sep. 3, 2002, the content of which is incorporated herein by reference.

### FIELD OF INVENTION

The invention relates to a light emitting diode, a support for its manufacture, as well as a method for manufacturing such a light emitting diode. In particular, the invention relates to a method for generating a microstructure periodic at the wavelength range of the light emitted by a light emitting layer, in the emitting layer of a light emitting diode. The invention also pertains to display screens incorporating these light emitting diodes. Display devices, and in particular display screens, are currently undergoing many developments.

### BACKGROUND

Organic light emitting diodes, known as OLEDs, constitute a technology that has given rise to more luminous, cheaper and more effective display modules and which could well be used to develop flat screens. Currently, three basic structures exist for light emitting diodes, which are shown in FIGS. 1 to 3. Schematically, known OLEDs have a stacked layer structure, including a layer forming the anode made of a transparent conductive oxide, hereafter called TCO, a hole injection layer, a hole transport layer, a light emitting layer, an electron transport layer and a layer forming the cathode. The most common transparent conductive oxide currently used to form the anode is a mixed indium tin oxide, called ITO (Indium Tin Oxide). A drawback of current OLEDs is their weak light emitting efficacy. This is the result of light emitted by the light emitting layer being trapped within the diode structure, because of the well-known wave guiding effect leading to light leaving only from the edges of the diode, where it is of no use for display applications. In fact, only the light emission leaving normally to the emission plane across the transparent conductive oxide (TCO) layer is usefully pixelized to form the image displayed by the OLED.

Another problem encountered with current OLEDs is the roughness of the transparent anode. This roughness results from the vacuum deposition technique currently used to deposit the material making up the anode. This roughness creates strong local variations in current density along the surface of pixels and thus causes accelerated ageing of the OLED. In addition, when the transparent conductive oxide making up the anode is ITO, the indium atoms from the ITO layer tend to migrate towards the layers surrounding it under the effect of an electric field.

### SUMMARY OF THE INVENTION

Attempts to solve this additional problem led the inventors to develop a light emitting diode structure, illustrated in FIG. 4, and which is the subject of a separate patent application filed on the same day as this application. The light emitting diode structure represented in FIG. 4 and described hereafter is not a structure of the prior art opposable to this application. Schematically, in the light emitting diode structure of the internal art of the applicants, the anode consists of two superimposed layers each consisting of a different or identical transparent conductive oxide. In the latter case, the two layers are deposited by a different coating method with the properties described hereafter. Moreover, the transparent conductive oxide layers can replace the hole injection layer present in OLEDs of the prior art.

Thus, an aspect of this invention proposes organic light emitting diodes with much reduced loss of light through the edges. By solving the problem of loss of light through the edges of the OLED, the invention also makes it possible, in certain embodiments, to solve the problem of roughness of the transparent conductive oxide layer constituting the anode. Furthermore, in certain embodiments, it is not only the problem of loss of light through the edges and the problem of roughness of the transparent conductive oxide layer forming the anode that are resolved, but also the problem of migration of indium from ITO towards the neighbouring layers.

For this purpose, the invention proposes a light emitting diode of a stacked-layer structure type including:

at least one layer forming the substrate,

at least one layer forming the anode,

at least one hole injection layer,

at least one hole transport layer,

at least one layer forming the light emitting layer,

at least one electron transport layer, and

at least one layer forming the cathode,

characterized in that it includes:

at least one layer of an inorganic material, deposited between at the least one layer forming the substrate and at the least one layer forming the light emitting layer, and wherein said inorganic layer includes, printed onto its surface, a structure periodic at the wavelength range of the light emitted by said at least one light emitting layer.

According to a first embodiment, said at least one inorganic material layer is an SiO₂ layer deposited between the at least one layer forming the substrate and the at least one layer forming the anode.

According to a second embodiment, said at least one organic material layer is one of the layers forming the anode.

According to a third embodiment, said at least one inorganic material layer is one of the layers forming the hole injection layer.

Preferably, in the second embodiment, said at least one layer forming the anode is a mixed indium tin oxide layer (ITO).

Also and preferably, in the second embodiment, said at least one layer forming the anode is a mixed antimony tin oxide layer (ATO).

Preferably, in the third embodiment, said at least one layer forming the hole injection layer is a mixed antimony tin oxide layer (ATO).

The invention also proposes a support for the manufacture of a light emitting diode which, in a first embodiment, consists of the following stacked layers:

at least one layer forming the substrate,

an SiO₂ layer whose surface is printed with a periodic structure in the desired wavelength range, and

at least one layer forming the anode.

The support of the invention for the manufacture of a diode consists, according to a second embodiment, of the following stacked layers:

at least one layer forming the substrate,

at least one layer forming the anode consisting of an inorganic material and whose outer surface is printed with a periodic structure in the desired wavelength range.

Moreover, the support of the invention for the manufacture of a diode consists, according to a second embodiment, of the following stacked layers:

at least one layer forming the substrate,

at least one layer forming the anode,

at least one layer forming the hole injection layer consisting of an inorganic material and whose outer surface is printed with a periodic structure in the desired wavelength range.

The invention proposes yet another process for generating a microstructure periodic at the wavelength range of the light emitted by the light emitting layer of a light emitting diode, said light emitting layer consisting of the following stacked layers:

at least one layer forming the substrate,

at least one layer forming the anode,

at least one hole injection layer,

at least one hole transport layer,

at least one layer forming the light emitting layer,

at least one electron transport layer, and

at least one layer forming the cathode,

characterized in that it comprises the following steps:

a) depositing by a sol-gel process at least one layer of an inorganic material between said layer forming the substrate and said at least one layer forming the light emitting layer, and

b) printing by soft lithography, a structure periodic at the wavelength range of light emitted by the at least one layer forming the light emitting layer, on the outer surface of said at least one layer deposited in step a).

In a first variant of this process, said at least one layer of inorganic material is an SiO₂ layer deposited directly on said at least one layer forming the substrate.

In a second variant of the process, said at least one layer of an inorganic material is one of the layers forming the anode.

Preferably, in the second variant of this process, said at least one inorganic material layer forming the anode is a mixed indium tin oxide layer.

In addition, in this second variant of the process, said at least one inorganic material layer forming the anode can be a mixed antimony tin oxide.

In a third variant of the process, said at least one inorganic material layer is one of the layers forming the hole injection layer.

Preferably, in this third variant of the process, said one of the layers forming the hole injection layers is a mixed antimony tin oxide layer.

In all variants of this process, said at least one inorganic material layer is printed prior to its consolidation by heating.

The invention also proposes a process for the manufacture of a light emitting diode, characterized in that it includes generating a microstructure periodic at the wavelength range of the light emitted by the light emitting layer of a light emitting diode using the process of the invention described above.

The invention further proposes a process for the manufacture of a light emitting diode, characterized in that it includes a step of use of the previously mentioned support of the invention.

In addition, the invention proposes a light-emitting diode display screen, characterized in that it includes at least one light emitting diode according to the invention.

Finally, the invention proposes a light-emitting diode display screen, characterized in that it includes at least one light emitting diode incorporating the above-described support of the invention.

Additional features and advantages of the present invention will be explained in the following detailed description. It is understood that the foregoing and following descriptions and examples are merely representative of the invention, and are intended to provide an overview for understanding the invention as claimed.

### BRIEF DESCRIPTION OF FIGURES

FIG. 1 is a schematic cross-section of a first OLED structure of the prior art,

FIG. 2 is a schematic cross-section of a second OLED structure of the prior art,

FIG. 3 is a schematic cross-section of a third OLED structure of the prior art,

FIG. 4 is a schematic cross-section of an OLED according to the internal art of the applicants,

FIG. 5 is a schematic cross-section of an OLED according to a first embodiment of the invention,

FIG. 6 is a schematic cross-section of an OLED according to a second embodiment of the invention,

FIG. 7 is a schematic cross-section of an OLED according to a third embodiment of the invention,

FIG. 8 is a schematic cross-section of an OLED according to a fourth embodiment of the invention,

FIG. 9 is a schematic cross-section of an OLED according to a fifth embodiment of the invention,

FIG. 10 is a schematic cross-section of an OLED according to a sixth embodiment of the invention.

### DETAILED DESCRIPTION OF THE INVENTION

The present invention provides a light emitting diode of the stacked-layer structure type, incorporating at least one layer made of an inorganic material between the layer forming the substrate and a layer forming the light emitting layer, in which a periodic structure at the wavelength range emitted by the light emitting layer is printed.

Also described is a method for generating a microstructure periodic with a wavelength range of the emitting layer of a light emitting diode. The method includes: depositing an inorganic material layer by a sol-gel process between the substrate and a light emitting layer, and printing the periodic structure onto the outer surface of this layer by soft lithography, as well as using this process for manufacturing a light emitting diode.

The invention will be described in reference to the accompanying Figures. The diagrams are not to scale, but are given merely to better illustrate how periodic structures in the OLED of the invention are achieved. The actual thickness of the various layers ranges from about 10 to about 100 nanometers and the period of the desired periodic structure ranges from about 200 to about 400 nanometers, while these dimensions are reversed in the Figures.

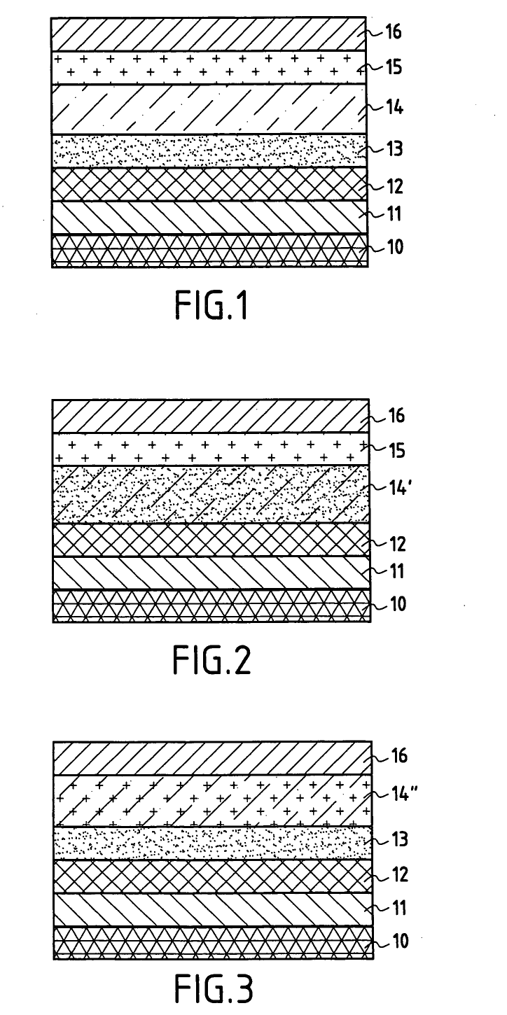

First, existing OLED structures known in the prior art in the article by Veronique Dentan et al., C.R. Acad. Sci. Paris, vol. 1, series IV, pages 425-435, entitled “Progress in molecular organic electroluminescent materials”, will be explained with reference to FIGS. 1 to 3.

The most complex OLED structure of the prior art is the so-called TL structure represented in FIG. 1.

As can be seen in FIG. 1, this structure consists of the following stacked layers, from bottom to top:

a layer forming the substrate 10, generally made of glass,

a layer forming the anode 11 made of a transparent conductive oxide, generally ITO, generally deposited by chemical vapour-phase deposition on the outer surface of the layer forming the substrate 10,

a hole injection layer 12, deposited on the outer surface of the layer forming the anode 11,

a hole transport layer 13, deposited on the outer surface of the layer forming the hole injection layer 12,

a layer forming the light emitting layer 14, deposited on the outer surface of the layer forming the hole injection layer 12,

a layer 15 forming the transport layer for electrons originating from the cathode 16, deposited on the outer surface of the layer forming the light emitting layer 14, and

a layer forming the cathode 16, deposited on the outer surface of the layer forming the electron transport layer 15.

The second basic type of OLED structure is that shown in FIG. 2. This is a DL-H type OLED. As can be seen in FIG. 2, the structure of DL-H OLEDs corresponds to the structure of TL OLEDs (FIG. 1) except that the layer called 14′ in FIG. 2 is made of a material that allows this layer 14′ to act both as a hole injection layer (13 in FIG. 1) and a light emitting layer (14 in FIG. 1).

The third basic type of existing OLED structure is the DL-E type OLED shown in FIG. 3.

The structure of DL-E type OLEDs corresponds to the structure of TL OLEDs (FIG. 1) except that in DL-E OLEDs the layer called 14″ in FIG. 3 is made of a material that allows this layer 14″ to act both as a light emitting layer (14 in FIG. 1) and an electron transport layer (15 in FIG. 1).

The applicants have developed other OLED structures. These structures are described in a patent application filed on the same day as this application and aims to solve problems related to the roughness of the surface of the transparent conductive oxide layers deposited by means of a vacuum deposition technique to form the anode of OLEDs of the prior art and, also, the problem related to the migration of indium when this transparent conductive oxide is ITO.

These structures represent the internal art of the applicants only and have never been disclosed prior to the filing of this application.

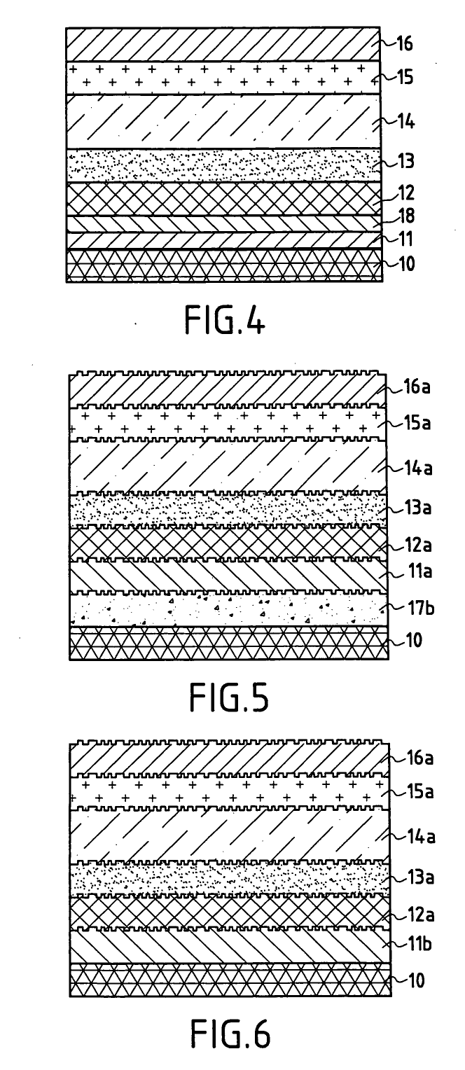

One of these structures is shown in FIG. 4. To solve the problems of surface roughness of transparent conductive oxide layers deposited by vacuum deposition to form the anode 11 of an OLED and to prevent the migration of indium ions towards the outer layers of an OLED when this anode 11 is made of ITO, the applicants have discovered that depositing onto the layer forming the anode 11 an additional layer (18 in FIG. 4) of a different transparent conductive oxide from that of the anode 11 by a sol-gel type process, the problem of surface roughness of the anode 11 deposited n the prior art by vacuum deposition was solved. Moreover, it was seen that, by carefully selecting the transparent conductive oxide forming the second layer 18, it was possible to considerably limit the migration of indium, when the anode was made of ITO, this layer 18 being used as a barrier against the migration of indium originating from the ITO layer under the effect of an electric field. This second layer 18 is preferably an ATO layer.

The applicants also discovered that the layer forming the anode 11 could itself be deposited by means of a sol-gel type process, in which case it did not have the rough surface of layers deposited by means of vacuum deposition.

As has already been explained in the patent application filed on the same day as this application, both layers 11 and 18 can form the anode or layer 11 can form the anode and layer 18 can act as a hole injection layer, in which case, in the structure represented in FIG. 4, layer 12 is no longer present.

To achieve these results, both types of transparent conductive metal oxide, making up layers 11 and 18 in the structures representing the internal art of the applicants, should be chosen so that the transmittance in the visible range of the structure forming layers 11 and 18 is at least equal to 80% and the electron extraction work of the second layer 18 is greater than the electron extraction work of layer 11, and in all cases greater than 4.6 electron volts, and preferably greater than 4.8 electron volts.

Advantageously, layer 11 is an ITO layer deposited by chemical vapour-phase deposition and layer 18 is an ATO or ITO layer deposited by a sol-gel process. However, layers 11 and 18 can both be deposited by a sol-gel process, in which case they consist of two differents TCOs.

In addition, as described above, layer 18, when it is made of ATO, can in some cases act as hole injection layer.

In all cases, both successive TCO layers 11 and 18 can consist of any transparent conductive oxide, be it a simple or mixed oxide or a mixture of oxides of at least one metal chosen from the group consisting of tin, zinc, indium, combined if necessary with at least one element from the group consisting of gallium, antimony, fluorine, aluminium, magnesium and zinc, this element entering into the composition of the mixed oxide or mixture of oxides, or acting as a doping agent for said oxide.

Examples of mixed oxides include:

Ga—In—O

Ga—In—Sn—O

Zn—In—O

Zn—In—Sn—O

Sb—Sn—O

Zn—Sn—O

Mg—In—O

Cd—In—O

Cd—Sn—O

Cd—Sn—In—O

which are all mixed oxides of at least one metal chosen from zinc, indium and tin.

Examples of doped oxides include tin oxide doped with fluorine (SnO₂:F) or tin oxide doped with antimony (SnO₂:Sb) or indium oxide doped with tin (In₂O₃:Sn).

In the description below, the term “mixed oxide” is used to designate oxide mixtures and doped oxides as well as mixed oxides per se.

In order to reduce loss of light from the light emitting layer 14, 14′, 14″, the invention proposes generating a microstructure periodic at the wavelength range emitted by the emitting layer 14, 14′, 14″ in the light emitting layer 14, 14′, 14″, 14a.

According to the invention, such a structure periodic at the wavelength range of the light emitted by the light emitting layer is generated in this emitting layer by printing the desired periodic structure onto a layer deposited between the layer forming the substrate 10 and the light emitting layer itself 14, 14′, 14″.

A method exists to print periodic microstructures in photosensitive resist layers using a photolithographic technique.

Nevertheless, the photolithographic technique is expensive and cannot be easily applied to print microstructures on films with a non-flat surface. Moreover, it is only directly applicable to photoresist type materials, and such materials are, in addition, difficult to be adhered or deposited on materials such as glass which is often used for OLED substrates.

To overcome these drawbacks, intrinsic to the use of a photoresist material and to the photolithographic technique, in printing periodic structures in the wavelength range emitted by the emitting layer of OLED diodes, the invention proposes printing this structure periodic at the wavelength range of the light emitted by the emitting layer onto a layer made of an inorganic material deposited between the substrate and the emitting layer.

Advantageously, this inorganic layer is deposited by a known process, the so-called sol-gel process, and printing in this layer of a structure periodic at the wavelength range emitted by the OLED emitting layer will be carried out by soft lithography which makes it possible to overcome the limitations of the photolithographic printing method.

The following layers deposited onto the layer in which the periodic microstructure is printed will be deposited by any suitable process, with the exception of a sol-gel process, as such a process would even out the surface of the printed layer and the periodic microstructure would no longer be found in the light emitting layer.

In other words, if the layers present on the printed layer itself were deposited by a sol-gel type process, the desired periodic structure would not be generated in the OLED light emitting layer.

However, the layers deposited under the printed layer can be deposited using any appropriate process which will be apparent to the one skilled in the art, in particular the sol-gel process.

Soft lithography is a method used for printing mechanically deformable layers and is described in “Soft Lithography”, Younan Xia and George M. Whitesides (Angew. Chem. Int. Ed. 1998, 37, 550-575).

In order to clarify the invention, several embodiment examples will be described as purely illustrative and not limiting examples

In these examples:

layers whose sole reference is a number called x or x′ or x″ are layers in which no structure periodic at the wavelength range emitted by the OLED light emitting layer is either printed or generated.

layers with the reference x followed by the letter “a” are layers in which a periodic structure in the wavelength range of light emitted by the OLED emitting layer has only been generated, and

layers with the reference x followed by the letter “b” are layers of an inorganic material in which a structure periodic at the wavelength range of light emitted by the OLED emitting layer has been printed, preferably by soft lithography.

### EXAMPLE 1

A first embodiment of the invention is represented in FIG. 5.

In this example, the OLED of the invention has the TL OLED structure of the prior art illustrated in FIG. 1, except that it includes an additional layer, called 1 7b in FIG. 5.

In this example, the layer forming the substrate 10 is preferably made of glass and the additional layer 17b consists of silica deposited by sol-gel. It is in this layer 17b that the periodic structure in the wavelength range of light emitted by the OLED emitting layer is printed by soft lithography, as illustrated in FIG. 5. Silica and glass are perfectly compatible materials. In addition, silica is also compatible with the material making up the anode (11a in FIG. 5), preferably ITO.

As can be seen in FIG. 5, the same desired periodic structure is generated in the light emitting layer 14a because of the presence of an additional layer 17b into which the desired periodic structure is introduced. In practice, the desired periodic structure is generated in all layers deposited on this layer 17b.

To obtain the structure represented in FIG. 5, the substrate 10 was coated with a silica layer by means of a sol-gel process. The desired periodic structure is printed in the silica layer while this layer, deposited by sol-gel, is still mechanically deformable. After this, the layer is consolidated by heating. This gives rise to layer 17b. Next, the following layers are successively deposited as in the known OLED manufacture process. However, for the reasons given earlier, the following layers must be deposited by means of a process other than sol-gel.

A SiO₂ layer can also be deposited in the same way between the layer forming the substrate 10 and the layer forming the anode 11 of DL-H and DL-E type OLEDs, represented in FIGS. 2 and 3 respectively, and such structures are structures belonging to the invention.

In the same manner, any material other than silica which is compatible with the materials forming the substrate and anode, and which can be deposited by a sol-gel process, can be used to obtain the OLED structures according to this example.

### EXAMPLE 2

A second embodiment of the invention is represented in FIG. 6.

The OLED in FIG. 6 has the TL OLED structure of the prior art illustrated in FIG. 1, except that in this embodiment, the layer forming the anode 11 is the layer in which the desired periodic structure is printed. The layer forming the anode containing the desired printed periodic structure on its surface is called 11b in FIG. 6.

Here again, as a result of printing the desired periodic structure in the layer forming the anode 11b, the desired periodic structure is generated in the light emitting layer 14a of the OLED.

Here again, the desired periodic structure is not only generated in the light emitting layer 14a but in all layers deposited on the layer forming the anode 11b.

To obtain the structure according to the second embodiment of the invention, the same process as in example 1 is used, that is to say a layer is deposited by means of a sol-gel process but, contrary to example 1, this is not an additional silica layer, which is not used in this embodiment, but a layer forming the anode made of a conductive oxide, preferably ITO, on the layer forming the substrate 10.

Prior to consolidation of the ITO material deposited by sol-gel, the desired periodic structure is printed by soft lithography. Layer 11b is then consolidated by heating and the following layers are deposited by the usual OLED manufacturing process.

It should be noted that in this embodiment, the problem of roughness of the layer forming the anode 11b made of a transparent conductive oxide, and more particularly ITO, is also solved, which further improves the performance of the OLED of the invention.

### EXAMPLE 3

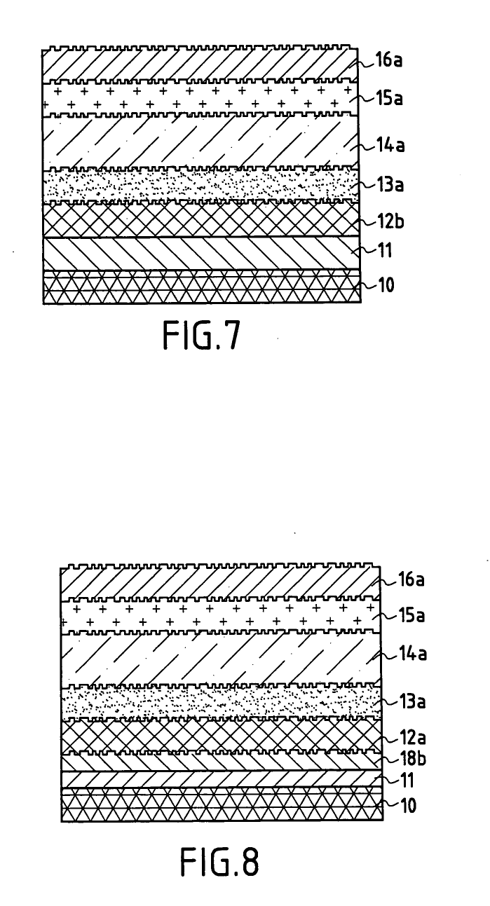

An OLED according to a third embodiment of the invention is represented in FIG. 7.

The OLED in FIG. 7 has the TL OLED structure of the prior art illustrated in FIG. 1, except that in this embodiment, the hole injection layer, called 12b in FIG. 7, was deposited by a sol-gel process and the desired periodic structure was printed by soft lithography on the outer surface of layer 12b.

The following steps in the OLED manufacturing process are, as in example 1, consolidation of layer 12b and successive deposition of the following layers by a process other than a gel-sol process.

This layer forming the hole injection layer is a layer made of a transparent conductive oxide different from the transparent conductive oxide making up the layer forming the anode, called 11 in FIG. 6.

Preferably, this layer, called 12b in FIG. 6, is a made of a mixed antimony tin oxide, called ATO hereafter.

As was explained earlier in the description of the applicants' internal art on how to resolve the problem of roughness of the transparent conductive oxide layer 11 deposited, in the prior art, by chemical vapour-phase deposition, the applicants discovered that such a layer, particularly an ATO layer, makes it possible not only to eliminate the problem of surface roughness of layer 11 but also to replace the hole injection layer used in the prior art, since it is deposited by a sol-gel process.

As in the first and second embodiments described in examples 1 and 2 above, by printing the desired periodic structure onto this layer made of a second transparent conductive oxide, the desired periodic structure is generated in the light emitting layer 14a, which is the desired outcome, just as it is generated in all following layers deposited on layer 12b.

Adding this layer 12b moreover solves the problem of the migration of indium ions towards the outer layers, as is the case in the prior art where layer 11 is made of ITO.

Thus, in this embodiment, not only the OLED presents loss of light from the light emitting layer 14a, through the OLED edges, but problems related to roughness of the layer forming the anode made of a transparent conductive oxide, particularly ITO, as well as the problem of migration of indium ions towards the outer layers from the layer forming the anode 11, when this is made of ITO, are all solved.

### EXAMPLE 4

An OLED structure according to a fourth embodiment of the invention is represented in FIG. 8.

This structure corresponds to the illustration in FIG. 4, i.e. a structure in which the anode consists of two superimposed layers, 11 and 18 in FIG. 4, in this case made of two different transparent conductive oxides.

However, in this structure, the desired periodic structure was printed by soft lithography on the outer layer, 18 in FIG. 4, which forms, along with layer 11, the OLED anode.

In this embodiment, layer 18 was deposited by a sol-gel process before printing.

As in the example, after printing, this layer is consolidated by heating and the following layers are deposited by any suitable process other than a sol-gel process.

Layer 11, which along with layer 18b forms the anode, may also have been deposited by vapour phase deposition under vacuum or by a sol-gel process.

In this embodiment, layer 18b is actually one of the layers forming the anode, contrary to the embodiment illustrated in FIG. 7 and described in example 3 above in which this layer is the hole injection layer, called 12a in FIG. 7.

In this embodiment, as in the embodiment described in example 3 and illustrated in FIG. 6, the problems of the loss of light from the edges of the light emitting layer, as well roughness of the ITO layer (11 in FIG. 8) deposited by chemical vapour phase deposition under vacuum, as well as migration of indium ions from this layer (11 in FIG. 8), are all solved.

### EXAMPLE 5

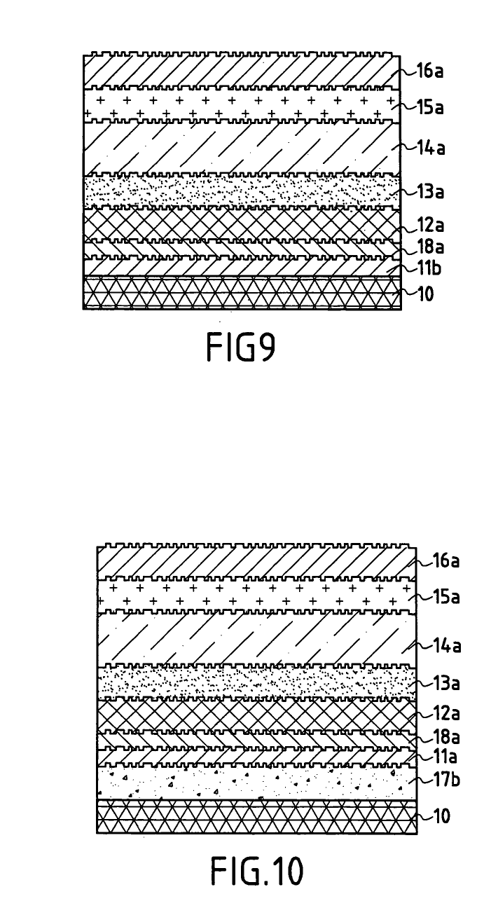

A structure according to a fifth embodiment of the invention is illustrated in FIG. 9.

This structure corresponds to the OLED represented in FIG. 4, i.e. a structure according to the internal art of the applicants.

In this embodiment, the first transparent conductive oxide layer, called 11 in FIG. 4, was deposited by a sol-gel process and the desired periodic structure was printed by soft lithography on the surface. This layer, called 11b in FIG. 9, is consolidated by heating and, as in the preceding examples, after consolidation, the following layers are successively deposited by any suitable process other than a sol-gel process.

Here again, not only the problem of loss of light through the edges of the OLED but also the problem of roughness of layer 11 and migration of atoms from this layer towards the outer layers are solved.

### EXAMPLE 6

An OLED structure according to a sixth embodiment of the invention is represented in FIG. 10.

This OLED structure corresponds to the OLED represented in FIG. 4, but in this structure, an additional layer called 17b in FIG. 10 has been added.

As in example 1, this layer can be a silica layer deposited by a sol-gel process and onto which the desired periodic structure has been printed by soft lithography.

Here again, the main drawbacks of OLEDs of the prior art, i.e. loss of light through the edges, roughness of the surface of the layer forming the anode (11a in FIG. 10) and migration of atoms from this layer 11a towards the outer layers are solved.

As can be seen, the principle of the invention to solve the problem of loss of light through the edges consists in depositing a layer by a sol-gel process or by any other technique allowing a periodic structure in the wavelength range emitted by the emitting layer of an OLED having the advantages of soft lithography to be printed between the layer forming the substrate 10 of an OLED and the light emitting layer of an OLED.

Under these conditions, other subjects of the invention incorporating such a layer are supports which can be produced and sold separately and which the buyer will use for manufacturing complete OLEDs by depositing the desired additional layers.

According to the invention, these supports consist, in a first embodiment, of a layer forming the substrate 10, coated with a layer made of an inorganic material, preferably silica preferably deposited by a sol-gel process in which a structure periodic at the desired wavelength range was printed by a sol-gel technique, a layer called 17b in FIGS. 1 and 10, said layer 17b being itself coated with at least one layer forming the anode.

In a second embodiment, the support of the invention consists of a layer forming the substrate called 10 in the Figures and of at least one layer made of an inorganic material, preferably deposited by a sol-gel process, onto the surface of which the desired periodic structure was printed by soft lithography.

In this embodiment, the inorganic material layer with the desired periodic structure printed on its surface forms the anode.

It is understood that the anode can be made of a single layer, 11b in FIG. 6, or of two superimposed layers, 11 and 18 in FIG. 10, at least one of the layers having been deposited by a sol-gel process and having the desired periodic structure printed on its surface.

Obviously, the invention is in no way limited to the embodiments described and illustrated above.

In particular, although the substrate 10 was described in the preceding examples as made of glass, this substrate can be made of any other appropriate material known to those skilled in the art, such as a glass-ceramics.

To the contrary, the invention includes all technical equivalents of the methods described, as well as combinations of these methods if they are carried out within the spirit of the invention.

The present invention has been described generally and in detail by way of examples and figures. Persons skilled in the art, however, will understand that the invention is not limited necessarily to the embodiments specifically disclosed, but that modifications and variations can be made without departing from the spirit of the invention. Therefore, unless changes otherwise depart of the scope of the invention as defined by the following claims, they should be construed as being included herein.

We claim:

1. A light emitting diode of the stacked layer structure type including:
at least one layer forming the substrate,
at least one layer forming the anode,
at least one hole injection layer,
at least one hole transport layer,
at least one layer forming the light emitting layer,
at least one electron transport layer,
at least one layer forming the cathode,
characterized in that it includes:
at least one layer made of an inorganic material, deposited between the at least one layer forming the substrate and the at least one layer forming the light emitting layer, and in that
said at least one layer made of an inorganic material has printed on its surface a structure periodic at the wavelength range emitted by said at least one light emitting layer.

2. The diode according to claim 1, wherein said at least one layer is made of an inorganic material is a SiO₂ layer deposited between the at least one layer forming the substrate and the at least one layer forming the anode.

3. The diode according to claim 1, wherein said at least one layer made of an organic material is one of the layers forming the anode.

4. The diode according to claim 1, wherein said at least one layer made of an inorganic material is one of the layers forming the hole injection layer.

5. The diode according to claim 3, wherein said at least one layer forming the anode is a layer consisting of a mixed indium tin oxide (ITO).

6. The diode according to claim 3, wherein said at least one layer forming the anode is a layer made of a mixed antimony tin oxide (ATO).

7. The diode according to claim 4, wherein said at least one layer forming the hole injection layer is a layer made of a mixed antimony tin oxide (ATO).

8. A support for manufacturing a diode according to claim 1, wherein said support consists of the following stacked layers:
at least one layer forming a substrate,
an SiO₂ layer whose surface is printed with a periodic structure in a desired wavelength range, and
at least one layer forming an anode.

9. A support for manufacturing a diode according to claim 3, characterized in that said support consists of the following stacked layers:
at least one layer forming a substrate,
at least one layer forming an anode made of an inorganic material and whose surface is printed with a structure periodic at a desired wavelength range.

10. A support for manufacturing a diode according to claim 4, characterized in that said support consists of the following stacked layers:
at least one layer forming a substrate,
at least one layer forming an anode,
at least one layer forming the hole injection layer consisting of an inorganic material and whose surface is printed with a structure periodic at a desired wavelength range.

11. A process for generating a microstructure periodic at a wavelength range of an emitting layer of a light emitting diode, said light emitting diode consisting of the following stacked layers:
at least one layer forming a substrate,
at least one layer forming an anode,
at least one hole injection layer,
at least one hole transport layer,
at least one layer forming the light emitting layer,
at least one electron transport layer,
at least one layer forming the cathode,
characterized in that the process includes the following steps:
a) depositing at least one layer made of an inorganic material by a sol-gel process between said at least one layer forming the substrate and said at least one layer forming the light emitting layer, and
b) printing by soft lithography a structure periodic at the wavelength range of the light emitted by said at least one layer forming the light emitting layer onto the surface of said at least one layer deposited in step a).

12. The process according to claim 11, wherein said at least one layer made of an inorganic material is a SiO₂ layer deposited directly onto said at least one layer forming the substrate.

13. The process according to claim 11, wherein said at least one layer made of an inorganic material is the layer forming the anode.

14. The process according to claim 7, wherein said at least one layer made of an inorganic material is the layer forming the anode consisting of a mixed indium tin oxide (ITO).

15. The process according to claim 13, wherein said at least one layer made of an inorganic material is one of the layers forming the anode and is a layer (18) made of a mixed antimony tin oxide (ATO).

16. The process according to claim 11, wherein said at least one layer made of an inorganic material is one of the layers forming the hole injection layer.

17. The process according to claim 16, wherein said one of the layers forming the hole injection layer is a layer consisting of a mixed antimony tin oxide (ATO).

18. The process according to any one of claim 11, wherein said at least one layer made of an inorganic material is printed before consolidation by heating.

19. The process for the manufacture of a light emitting diode characterized in that it includes generating a microstructure periodic at the wavelength range of light emitted by the emitting layer of a light emitting diode by a process according to claim 11.

20. The process for the manufacture of a light emitting diode characterized in that it includes a step where a support according to any one of claims 8, 9, or 10 is used.

21. A light-emitting diode display screen characterized in that said screen includes at least one light emitting diode according to claim 1.

22. A light-emitting diode display screen characterized in that said screen includes at least one light emitting diode incorporating the support according to any one of claims 8, 9, or 10.
